(19) United States
(12) Patent Application Publication
(10) Pub. No.: US 2006/0281345 A1
(43) Pub. Date: Dec. 14, 2006

(54) Self-locking junction box

(76) Inventor: Malcolm G. Caswell, St. Stephen (CA)

Correspondence Address: Patrick D Archibald;Lambert & Associates, 92 State Street, Boston, MA, 02109, US

(21) Appl. No.: 10/552,043

(22) PCT Filed: Apr. 2, 2004
(86) PCT No.: PCT/CA04/00499

§ 371 Date: Oct. 14, 2005

(30) Foreign Application Priority Data
Apr. 2, 2003 (CA) 2,424,238

(51) Int. Cl. H05K 1/00

(52) U.S. Cl. 439/76.2

(57) ABSTRACT

A device, namely, a pre-wired, self-locking junction box, namely, a self-locking junction box, being a manufactured housing of non-conductive material having a closed top and a closed bottom and being comprised of two parts, a lower bottom part and an upper top part being suitably adapted in size to releasably engage said lower part, and said housing having a plurality of inlets about its circumference to receivably engage electrical cable and, furthermore, a second box, namely, a pre-wired terminal connector, being a housing of non-conductive material having a plurality of inlets and 3 layers of conductive material for live, neutral and ground connections, respectively, each of said layers insulated from the other, wherein said pre-wired terminal connector is housed by said first housing and each of said live, neutral and ground conductive layers are disposed in relation to the inlets of the first and second housing to securely receive the live, neutral and ground electrical cables to make an electrical circuit. A third box of nonconductive material housing a layer of conductive material with inlets at opposite ends to receivably engage electrical cable to make an electrical circuit, namely, a single wire connector. Single and three pronged wire release tools are used to release the bare wire ends from the spring lock connectors of the pre-wired terminal connector and the single wire connector.

### FIELD OF THE INVENTION

The present invention relates to a device for electrical wiring, namely, a pre-wired, self-locking junction box for use in domestic, commercial and industrial buildings.

### DESCRIPTION OF THE PRIOR ART

The use of pre-wired electrical junction boxes in the wiring of domestic, industrial and commercial buildings is well known.

Several prewired junction boxes which allow electricians to make wiring connections without having to manually twist-connect wires have been disclosed, such as U.S. Pat. Nos. 2,410,287; 2,433,917; 2,920,303; and 3,885,852. These patents disclose systems whereby special modular fixtures are plugged into single-purpose junction boxes, thereby reducing the labor required to implement an electrical circuit.

There are several disadvantages to these prior art devices: first, they require specially constructed fixtures (as opposed to industry-standard fixtures); second, they involve complex manufacturing processes; and third, their functionality is limited to only one operation. For these reasons, they have not found commercial success.

Other, more recent prewired junction boxes include U.S. Pat. Nos. 3,922,478; 4,165,443; and 4,336,418. These patents disclose systems containing electrical busses whereby electrical connections are made by inserting cables and special fixtures into the junction box.

These devices also have drawbacks that have limited their commercial success, including: requiring the use of specially-manufactured fixtures; not providing lateral support to the electrical service cables; and requiring reconfiguration of the internal busses to create many of the desired circuits.

Reference is made to U.S. Pat. No. 4,924,032 (Akins), which discloses a universal junction box with a plurality of internal busses for making all of the standard connections required in conventional electrical wiring. It allows the electrician to connect standard electrical circuits without manipulating the busses and it uses standard electrical fixtures, all without requiring twist connectors. Furthermore, it allows electrical service connections to be made by inserting electrical cables into openings in the box, both making connections with the busses and providing lateral support to the cables.

However, the '032 device connects the service cables by clamping onto the exposed conductive metal of the cable wires. It does not have a means to clamp onto the insulation of the cable jacket, therefore the lateral support to the cable is limited. Second, the method of connecting the service cable wires in the '032 structure restricts the electrician to choosing highly conductive (and, therefore, highly expensive) materials, such as copper, for wire conductors. Less expensive aluminum cannot be used because as current passes therethrough, the wire heats up; as it heats up it expands, forcing the connector to expand with it; when it cools down it contracts. However, the connector does not contract with it; therefore, when the wire is cool, it has a poor electrical connection. Third, its internal bus arrangement requires the use of expensive 4-wire cable in implementing a three-way switch; this is a disadvantage because 4-wire cable is more expensive than 3-wire cable and electricians prefer not to have to carry the added bulk of 4-wire cable in addition to the 3-wire cable they normally carry. Fourth, the polygonal shape of the box makes it impossible to connect several boxes together to form a “multi-ganged” arrangement, whereby boxes are placed next together to form dual switches and dual receptacles. Fifth, the arrangement of the busses next to the wall of the box made it so that the metal of energized wires is exposed, thus creating a potential safety hazard. Sixth, the wires are not automatically aligned with their respective busses, thus the electrician is required to perform the alignment task thereby increasing the cost of wiring to the electrical contractor.

The invention herein overcomes many of the above noted shortcomings.

### SUMMARY OF THE INVENTION

The object of the present invention is to simplify the task of constructing electrical circuits in domestic, commercial and industrial buildings by providing a pre-wired connector block and self-locking junction box that is suitable for use in making wiring connections typically found in the routine installation of electrical services.

With the present invention, wiring connections are made without the cumbersome, tedious task of first threading the cable through the junction box holes. The present invention is self-locking and, as such, requires no screw, bolts, or cables to tighten in order to make secure connections. The possibility for electrical shocks and short circuits is eliminated. The self-locking junction box is secure and easily unlocked for additional wiring or removal of wires. The bare wire ends are safely contained within the junction box. Furthermore, the box can be easily recycled for other wiring jobs.

### BRIEF DESCRIPTION OF THE DRAWINGS

FIG. 1 illustrates a top view of the top part of an embodiment of the housing of the self-locking junction box.

FIG. 2 illustrates a top view of the bottom part of an embodiment of the housing of the self-locking junction box.

FIG. 3 illustrates a side view of the top part of an embodiment of the housing of a self-locking junction box.

FIG. 4 illustrates a side view of the bottom part of an embodiment of the housing of a self-locking junction box.

FIG. 5 illustrates a side view of the locked, two part housing of a self-locking junction box.

FIG. 6 illustrates a cross-sectional view of the of the electrical cable inlet of an embodiment of the housing of a self-locking junction box.

FIG. 7 illustrates a cross-sectional view of the self-locking device of an embodiment of the housing of a self-locking junction box.

FIG. 8 illustrates a top, cross-sectional view of the box housing layers of conductive material in an embodiment of a connector block.

FIG. 9 illustrates a side view of the box housing layers of conductive material in an embodiment of a connector block.

FIG. 10a) illustrates a top, cross-sectional view of the integrated spring lock connector of the box housing layers of conductive material in an embodiment of a connector block.

FIG. 10b) is a side view of the integrated spring lock connector of the box housing layers of conductive material in an embodiment of a connector block.

FIG. 11 is a top view of the single wire connector in an embodiment of a connector block.

FIG. 11a side, cross-sectional view of the single wire connector in an embodiment of a connector block.

FIG. 12 is a front view of the special release tool.

FIG. 12 a is a top view of the special release tool.

### DESCRIPTION OF THE PREFERRED EMBODIMENT

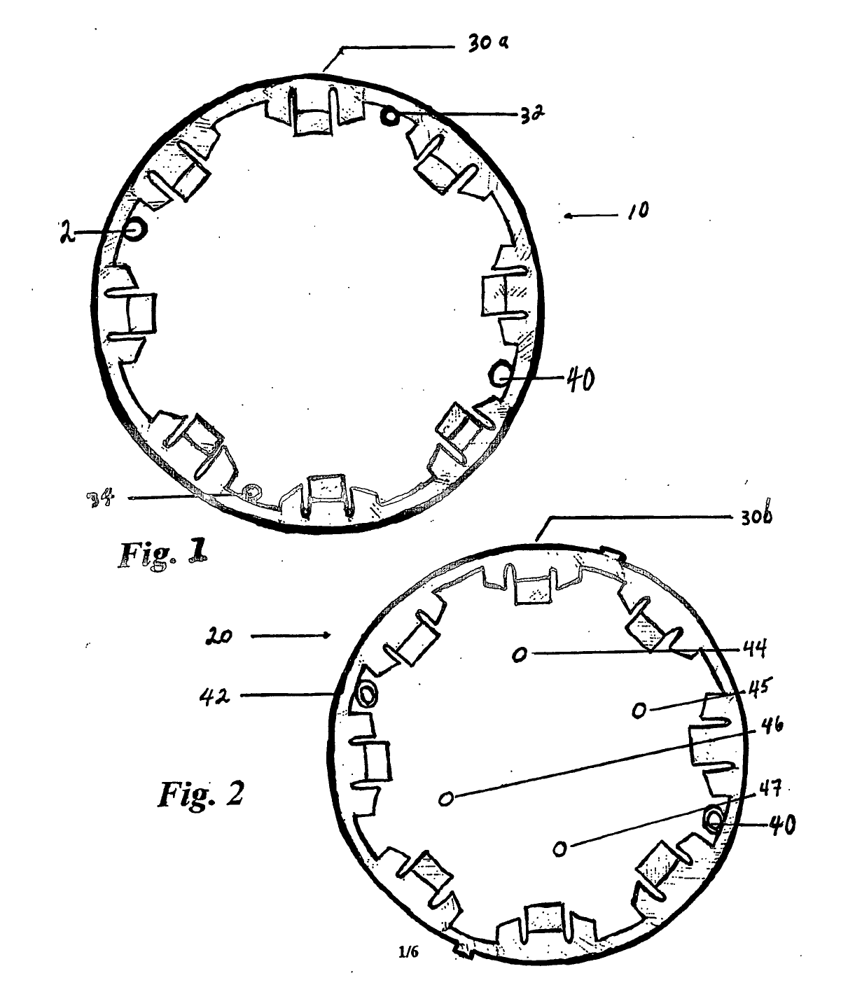

Referring to FIG. 1, an embodiment of the present invention is illustrated as the top part of the self-locking junction box 10, said top part being larger in diameter than the bottom part of the self-locking junction box 20 illustrated in FIG. 2. Both the top part and the bottom part complement each other in such a way that when engaged, inlets 30a and 30b permit the securing and the passage of electrical cable. Holes 40 and 42 in the top part and the bottom part also, when aligned, permit the insertion of an attachment means, including a screwnail, to securely fasten the self-locking junction box to, for example, a stud, if the self-locking junction box is to support a fixture; otherwise, holes 44, 45, 46, and 47 in the bottom part of the self-locking junction box, 20, permit the insertion of an attachment means, including a screwnail, to securely fasten the self-locking junction box.

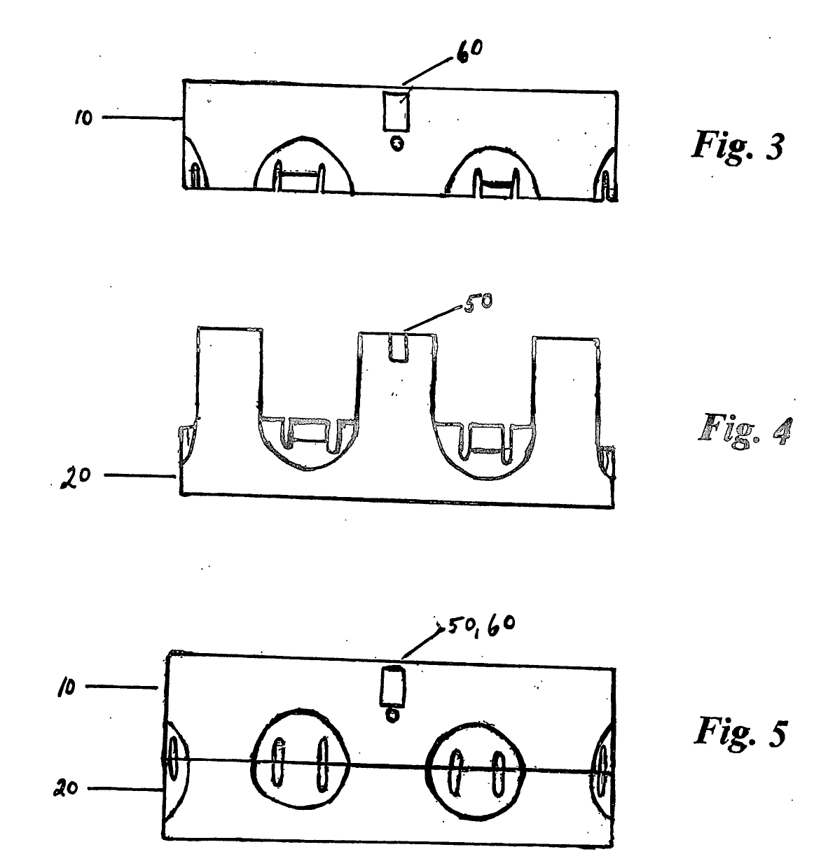

Referring to FIG. 3, an embodiment of the present invention is illustrated as the side view of the top part of the self-locking junction box 10. When the top part of the self-locking junction box 10 is properly aligned with the lower part of the self-locking junction box 20, a barb 50 in the lower part of the self-locking junction is ready to engage with a barb hole 60 in the upper part of the self-locking junction box 20, as shown in FIG. 4. FIG. 5 illustrates the top part and the bottom part of the self-locking junction box 10 in the engaged position with the lower part of the self-locking junction box 20 such that the barb 50 is secure with the barb hole 60. Referring to FIG. 1, holes 32 and 34 in the top part of the self-locking junction box 10 are proximate to each barb hole 60 and permit the insertion of means for disengaging the barb 50 from each barb hole 60.

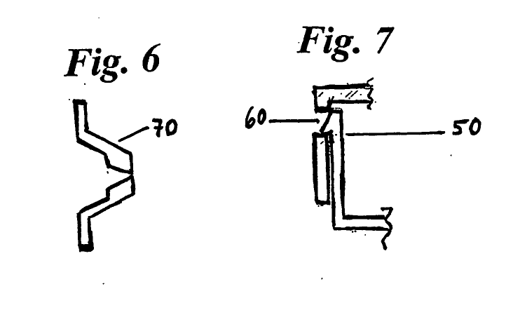

Referring to FIG. 6, an embodiment of the present invention is illustrated as the cable inlet 70 to permit the secure passage of electrical cable through the self-locking junction box in the engaged position.

Referring to FIG. 7, an embodiment of the present invention is illustrated as the barb 50 of the bottom part of the self-locking junction box engaging the barb hole 60 of the top part of the self locking junction box.

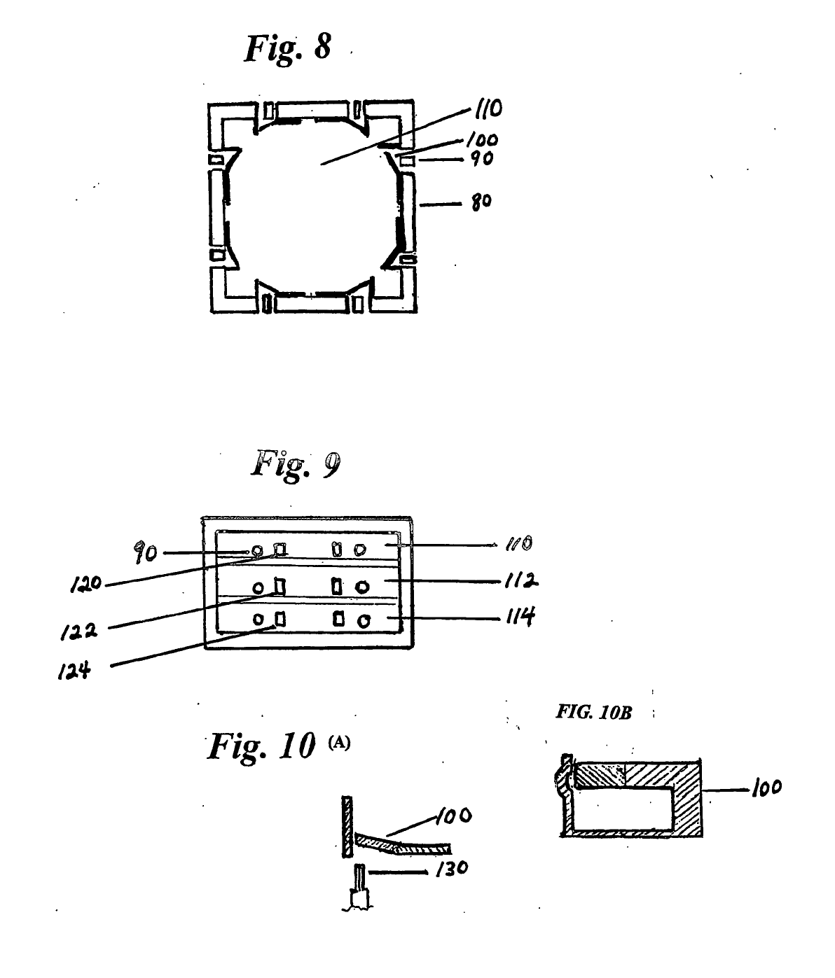

Referring to FIG. 8, an embodiment of the present invention is illustrated as the pre-wired terminal connector 80 showing wire inlets 90 to receive the bare end of electrical wire for contact against the spring lock connector 100, an integral component of the conductive layer 110.

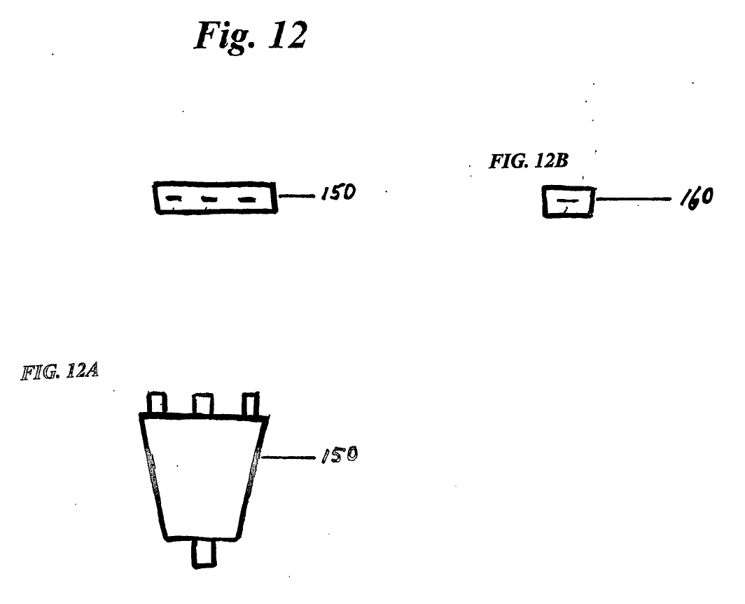

Referring to FIG. 9, an embodiment of the present invention is illustrated as the pre-wired terminal connector showing the three conductive layers 110, 112, 114, from top to bottom, as live, neutral and ground, with circular wire inlets 90 to receive the bare wire end. Rectangular holes 120, 122, 124 adjacent to each wire inlet are adapted to receive the ends of the wire release tool, as shown in FIG. 12, that, when inserted, release the spring lock connector 100 and permit the release of the bare wire end.

Referring to FIG. 10a, an embodiment of the present invention is illustrated as the bare wire end 130 to be inserted into the spring lock connector 100. Referring to FIG. 10b, an embodiment of the present invention is illustrated as an end view of the spring lock connector 100.

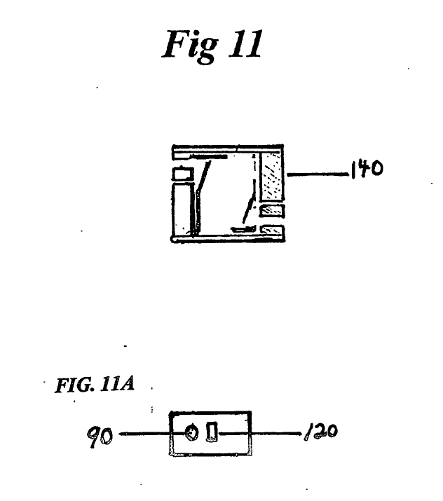

Referring to FIG. 11, an embodiment of the present invention is illustrated as the single wire connector 140 for housing in the self locking junction box. FIG. 11a shows a circular wire inlet 90 to receive the bare wire end. As shown in FIG. 11a, a rectangular hole adjacent to the wire inlet is adapted to receive the end of the single prong wire release tool 160 shown in FIG. 12b.

Referring to FIG. 12, an embodiment of the present invention is illustrated as an end view of the three pronged wire release tool 150. The wire release tool, as shown in FIG. 12a, is to be inserted into the three rectangular holes 120, 122, 124 of the pre-wired terminal connector shown in FIG. 9. FIG. 12b shows an end view of single pronged wire release tool 160 for insertion into the rectangular hole of the single wire connector 140 as shown in FIG. 11a.

What is claimed is a pre-wired, self-locking junction box comprising:

1. a first housing of non-conductive material having a closed top and a closed bottom, said first housing being comprised of two parts, a lower bottom part and an upper top part, said top part being suitably adapted in size to releasably enage said lower part, and said first housing having a plurality of inlets about itself to receivably engage electrical cable;
a. a second box housing of non-conductive material having a plurality of inlets and 3 layers of conductive material for live, neutral and ground connections, respectively, each of said layers insulated from the other;
b. characterized in that said second box is housed by said first housing and each of said live, neutral and ground conductive layers are disposed in relation to the inlets of the first and second housing to securely receive the live, neutral and ground electrical cables to make an electrical circuit.

2. The junction box of claim 1 characterized in that at least one hole through each of the upper top part and lower bottom part of said housing are aligned to permit passing therethrough an attachment means to secure said junction box.

3. The junction box of claim 2 characterized in that a grommet of non-conductive material with at least two holes passing therethrough is affixed to the upper surface of the upper top part to receive electrical cables from a fixture.

4. The junction box of claim 1 characterized in that at least one hole through the lower bottom part of said housing to permit passing therethrough an attachment means to secure said junction box.

5. The junction box of claim 1 characterized in that the said 3 layers of conductive material are integrated with spring lock connectors to securely engage electrical cables.

6. The junction box of claim 4 characterized in that said second box disposes of holes passing therethrough to receive a three pronged insulated wire release tool to engage said spring lock connectors to permit disengaging the electrical cables.

7. a first housing of non-conductive material having a closed top and a closed bottom, said first housing being comprised of two parts, a lower bottom part and an upper top part, said top part being suitably adapted in size to releasably enage said lower part, and said first housing having a plurality of inlets about its circumference to receivably engage electrical cable;
a. a third box of non-conductive material housing a layer of conductive material with inlets at opposite ends to receivably engage electrical cable to make an electrical circuit;
characterized in that said third box is housed by said first housing.
